(19) United States
(12) Patent Application Publication
(10) Pub. No.: US 2022/0187797 A1
(43) Pub. Date: Jun. 16, 2022

(54) SUBSTRATE TREATING APPARATUS AND SUBSTRATE TREATING METHOD

(71) Applicant: SEMES CO., LTD., Cheonan-si (KR)

(72) Inventor: SUNG MIN LIM, Cheonan-si (KR)

(73) Assignee: SEMES CO., LTD., Cheonan-si (KR)

(21) Appl. No.: 17/551,204

(22) Filed: Dec. 15, 2021

(30) Foreign Application Priority Data
Dec. 15, 2020 (KR) 10-2020-0175529

(51) Int. Cl. G05B 19/4155; H01L 21/677; H01J 37/32

(52) U.S. Cl. CPC G05B 19/4155; H01L 21/67727; G05B 2219/45031; H01J 37/32899; H01J 37/32733

(57) ABSTRACT

Disclosed is a substrate treating apparatus for performing treatment of a plurality of substrates. The apparatus may include a load port configured to load a conveying container for receiving the plurality of substrates; a plurality of process chambers configured to perform the treatment of the substrates; a transfer chamber configured to convey the substrates between the load port and the process chamber; and a control unit configured to control the transfer chamber to convey the substrates by applying a flow recipe, wherein the control unit may control a mode of the corresponding process chamber to be changed when there is a process chamber where abnormality occurs among the plurality of process chambers included in the flow recipe while the flow recipe is applied.

### CROSS-REFERENCE TO RELATED APPLICATIONS

This application claims priority to and the benefit of the Korean Patent Application No. 10-2020-0175529 filed in the Korean Intellectual Property Office on Dec. 15, 2020, the entire contents of which are incorporated herein by reference.

### TECHNICAL FIELD

The present invention relates to a substrate treating apparatus and a substrate treating method, and more particularly, to the invention characterized by a control unit for controlling a flow recipe.

### BACKGROUND ART

In a semiconductor treating apparatus, there is a single type substrate treating apparatus of loading a front-opening unified pod (FOUP) in a loading part, and treating a substrate taken out in the FOUP in a plurality of process chambers in sequence or in parallel. As an example of such a type of substrate treating apparatus, a substrate cleaning apparatus for cleaning a substrate includes a loading part loading a plurality of FOUPs, a cleaning chamber which performs a cleaning process by supplying a cleaning liquid to a treated surface of the rotating substrate or performs a scrub cleaning by touching a scrubber such as a brush on the surface thereof, and a conveying chamber conveying the substrate between the process chamber and the FOUPs.

In addition, in the case of performing the treatment for the substrate, a treating recipe set on the substrate (hereinafter, a treating recipe to be performed based on the setting for the substrate is referred to as a process job (PJ)) and a conveying schedule of the substrate as a group unit of the process job based on an allocated sequence for a control job (CJ) set in the FOUP are prepared. The substrate is discharged from the FOUP based on the conveying schedule, conveyed to a predetermined process chamber and treated, and then returns to the original FOUP.

In the related art, a user prepares a flow recipe and a process recipe according to a state of the process chamber and selects a usable process chamber PM to perform a job. At this time, when there is a problem in the process chamber to be used, the substrate of the currently performing job is controlled so as not to be introduced. In order to use the corresponding process chamber, normality is confirmed through an aging job and a sample job and then it is determined to use the process chamber. However, according to such an existing method, the normalized process chamber is used by executing a new FOUP, and thus, there is a problem that loss due to an idle time is increased according to a logistics situation of the lines.

### SUMMARY OF THE INVENTION

The present invention has also been made in an effort to provide a substrate mode control method for efficient treatment of a substrate.

The problem to be solved by the present invention is not limited to the above-mentioned problems, and the problems not mentioned will be clearly understood by those skilled in the art from the present specification and the accompanying drawings.

An exemplary embodiment of the present invention provides a substrate treating apparatus that performs the treatment of a plurality of substrates.

The apparatus may include a load port configured to load a conveying container for receiving the plurality of substrates; a plurality of process chambers configured to perform the treatment of the substrates; a transfer chamber configured to convey the substrates between the load port and the process chamber; and a control unit configured to control the transfer chamber to convey the substrates by applying a flow recipe, wherein the control unit may control a mode of the corresponding process chamber to be changed when there is a process chamber where abnormality occurs among the plurality of process chambers included in the flow recipe while the flow recipe is applied.

According to the exemplary embodiment, the mode may be any one of a maintenance mode, an interlock mode, an offline mode, and an online mode.

According to the exemplary embodiment, the control unit may determine whether or not to introduce the substrate according to each mode for the process chamber where the abnormality occurs.

According to the exemplary embodiment, the control unit may control the substrate not to be introduced to the corresponding process chamber in the maintenance mode, the interlock mode, and the offline mode, and control the substrate to be introduced to the corresponding process chamber in the online mode.

According to the exemplary embodiment, the control unit may control the change of the mode even when a job is performing according to the flow recipe.

According to the exemplary embodiment, the control unit may control the same flow recipe to be applied to the plurality of substrates.

According to the exemplary embodiment, the same flow recipe may be set to include all of the plurality of process chambers.

According to the exemplary embodiment, the control unit may be interlocked with a host.

According to the exemplary embodiment, the mode of the process chamber may be changed using a SECS Message of the host.

An exemplary embodiment of the present invention provides a method for prerforming substrate treatment using a plurality of process chambers.

The method may include the steps of: setting a flow recipe of substrates to be treated in the plurality of process chambers; and controlling a transfer chamber conveying the substrates to be operated by applying the flow recipe, wherein the controlling of the transfer chamber conveying the substrates to be operated by applying the flow recipe may include confirming a process chamber having abnormality among the plurality of process chambers included in the flow recipe.

According to the exemplary embodiment, the method may further include confirming a process chamber having abnormality among the plurality of process chambers and controlling a mode of the corresponding process chamber to be changed.

According to the exemplary embodiment, the mode may be any one of a maintenance mode, an interlock mode, an offline mode, and an online mode.

According to the exemplary embodiment, the confirming of the process chamber having abnormality among the plurality of process chambers and controlling of the mode of the corresponding process chamber to be changed may include determining the introduction of the substrate according to each mode for the process chamber having the abnormality.

According to the exemplary embodiment, the substrate may be controlled so as not to be introduced to the corresponding process chamber in the maintenance mode, the interlock mode, and the offline mode, and the substrate may be controlled to be introduced to the corresponding process chamber in the online mode.

According to the exemplary embodiment, the change of the mode may be controlled even when the job is performing according to the flow recipe.

An exemplary embodiment of the present invention provides a substrate treating apparatus for performing treatment for a plurality of substrates.

The apparatus may include a plurality of load ports configured to load a conveying container for receiving the plurality of substrates; a plurality of process chambers configured to perform the treatment of the substrates; a transfer chamber configured to convey the substrates between the plurality of load ports and the plurality of process chambers; and a control unit configured to control the transfer chamber to convey the substrates by applying a flow recipe, wherein the plurality of load ports may include a first load port and a second load port, the plurality of process chambers may include a first process chamber, a second process chamber, and a third process chamber, the flow recipe of the first load port and the second load port may be the order of the first process chamber and the third process chamber, and the control unit may control the flow recipe to be performed by including the second process chamber when the second process chamber is operable during the flow recipe treatment of the second load port.

According to the exemplary embodiment of the present invention, it is possible to increase the substrate treatment efficiency as compared with the related art.

Further, according to the exemplary embodiment of the present invention, it is possible to decrease an idle time of the substrate as compared with the related art.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a plan view illustrating a substrate treating apparatus according to an exemplary embodiment of the present invention.

FIG. 2A is a diagram for describing performing substrate treatment using a flow recipe in a conventional method.

FIG. 2B is a diagram for describing performing substrate treatment using a flow recipe in a method according to the present invention.

FIG. 3 is a flowchart illustrating a substrate treating method according to the present invention.

### DETAILED DESCRIPTION

Advantages and features of the present invention, and methods for accomplishing the same will be more clearly understood from embodiments to be described below in detail with reference to the accompanying drawings. However, the present invention is not limited to the exemplary embodiments set forth below, and may be embodied in various different forms. The exemplary embodiments are just for rendering the disclosure of the present invention complete and are set forth to provide a complete understanding of the scope of the invention to a person with ordinary skill in the technical field to which the present invention pertains, and the present invention will only be defined by the scope of the claims.

All terms (including technical or scientific terms) used herein have the same meanings as meanings which are generally received by universal techniques in the related art to which the invention pertains, unless defined. Terms defined in generally dictionaries shall be construed to have the same meanings as those in the context of related arts and/or the present application, and shall not be generalized or construed in excessively formal meanings unless clearly defined herein.

It is also to be understood that the terminologies used herein are for the purpose of describing exemplary embodiments and are not intended to limit the present disclosure. In this specification, singular expressions used herein include plurals expressions unless otherwise particularly mentioned in the context. It will be appreciated that the word “comprise” and/or verb variations such as “comprises” or “comprising” used herein means that the aforementioned compositions, components, constituent elements, steps, operations and/or devices do not exclude the existence or addition of one or more other compositions, components, constituent elements, steps, operations and/or devices. In this specification, the term ‘and/or’ indicates each of listed configurations or various combinations thereof.

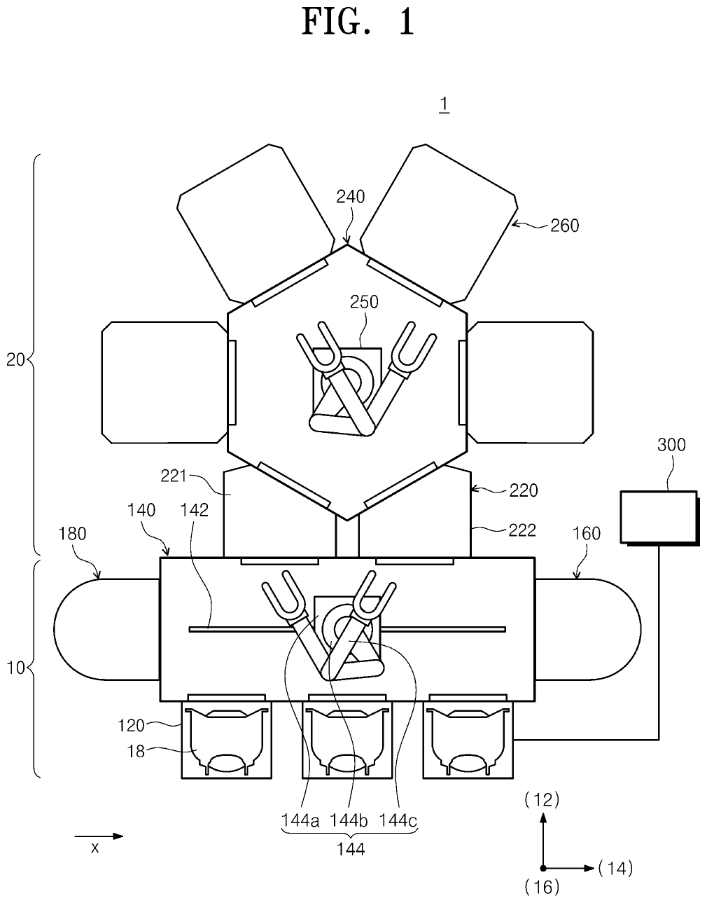

FIG. 1 is a plan view illustrating a substrate treating apparatus according to an exemplary embodiment of the present invention. The substrate treating apparatus according to the exemplary embodiment of the present invention may be a substrate treating apparatus of etching the substrate using plasma. However, the present invention is not limited thereto, and may be applicable to various types of devices for treating the substrate by various methods.

Referring to FIG. 1, a substrate treating apparatus 1 has an index module 10 and a treating module 20, and the index module 10 has a load port 120, an index frame 140, a buffer unit 160, and an alignment chamber 180. The load port 120, the index frame 140, and the treating module 20 are sequentially arranged in line.

Hereinafter, a direction in which the load port 120, the index frame 140, and the treating module 20 are arranged is referred to as a first direction 12, a direction vertical to the first direction 12 when viewed from the top is referred to as a second direction 14, and a direction vertical to a plane including the first direction 12 and the second direction 14 is referred to as a third direction 16.

In the load port 120, a container 18 in which a plurality of substrates W is received is disposed. A plurality of load ports 120 are provided and arranged in a line in the second direction 14. In FIG. 1, it is illustrated that three load ports 120 are provided. However, the number of load ports 120 may increase or decrease in accordance with a condition such as the process efficiency, a footprint, and the like of the treating module 20.

The container 18 is formed with a slot (not illustrated) provided to support the edge of the substrate W. A plurality of slots is provided in the third direction 16, and the substrates W are located in the container to be stacked while being spaced apart from each other in the third direction 16. As the container 18, a front opening unified pod (FOUP) may be used.

The index frame 140 conveys the substrate W between the container 18 seated in the load port 120, the buffer unit 160, the alignment chamber 180, and the treating module 20. The index frame 140 is provided with an index rail 142 and an index robot 144. The index rail 142 is provided with a longitudinal direction in parallel with the second direction 14. The index robot 144 is provided on the index rail 142 and is moved linearly to the second direction 14 along the index rail 142.

The index robot 144 has a base 144a, a body 144b, and an index arm 144c. The base 144a is provided to be movable along the index rail 142. The body 144b is coupled to the base 144a. The body 144b is provided to be movable along the third direction 16 on the base 144a.

In addition, the body 144b is provided to be rotatable on the base 144a. The index arm 144c is coupled to the body 144b and is provided to move forward and backward to the body 144b. A plurality of index arms 144c is provided to be individually driven.

The index arms 144c are disposed to be stacked while being spaced apart from each other along the third direction 16. Some of the index arms 144c may be used when the substrates W are conveyed from the treating module 20 to the container 18 and others thereof may be used when the substrates W are conveyed from the container 18 to the treating module 20. As a result, the index robot 144 may prevent particles generated from the substrate W before the process treatment in the process of introducing and discharging the substrate W from being attached to the substrate W after the process treatment.

The buffer unit 160 temporarily stores the substrate W. The buffer unit 160 performs a post-treatment process of post-treating the substrate W treated in the treating module 20. The post-treatment process may be a process of purging purge gas on the substrate W. The buffer unit 160 is located on one side of the index frame 140.

The treating module 20 includes a loading chamber 220, a transfer chamber 240, and a plurality of process chambers 260. The loading chamber 220 is disposed between the index chamber 140 and the transfer chamber 240. The loading chamber 220 replaces a normal-pressure atmosphere of the index module 10 with a vacuum atmosphere of the treating module 20 with respect to the substrate W to be introduced to the treating module 20, or replaces the vacuum atmosphere of the treating module 20 with the normal-pressure atmosphere of the index module 10 with respect to the substrate W to be discharged to the index module 10. The loading chamber 220 provides a space in which the substrate W is left before the substrate W is conveyed between the transfer chamber 240 and the index frame 140. The loading chamber 220 includes a load lock chamber 221 and an unload lock chamber 222.

The load lock chamber 221 temporarily stores the substrate W conveyed to the treating module 20 from the index module 10. The load lock chamber 221 maintains the normal pressure atmosphere in an idle state and is blocked with respect to the treating module 20, while maintains an opened state with respect to the index module 10. When the substrate W is introduced to the load lock chamber 221, an inner space is sealed with respect to each of the index module 10 and the treating module 20. Thereafter, the inner space of the load lock chamber 221 is replaced from the normal pressure atmosphere to the vacuum atmosphere and is opened with respect to the treating module 20 while being blocked with respect to the index module 10.

The unload lock chamber 222 temporarily stores the substrate W conveyed to the index module 10 from the treating module 20. The unload lock chamber 222 maintains the vacuum atmosphere in the idle state and is blocked with respect to the index module 10, while maintains an opened state with respect to the treating module 20. When the substrate W is introduced to the unload lock chamber 222, an inner space is sealed with respect to each of the index module 10 and the treating module 20. Thereafter, the inner space of the unload lock chamber 222 is replaced from the vacuum atmosphere to the normal pressure atmosphere and is opened with respect to the index module 10 while being blocked with respect to the treating module 20.

The transfer chamber 240 conveys the substrate W among the load lock chamber 221, the unload lock chamber 222, and the plurality of process chambers 260. The transfer chamber 240 may be provided in a hexagonal shape. Optionally, the transfer chamber 240 may be provided in a rectangular or pentagonal shape. On the circumference of the transfer chamber 240, the load lock chamber 221, the unload lock chamber 222, and the plurality of process chambers 260 are located. A conveying space for conveying the substrate W is provided in the transfer chamber 240.

The transfer chamber 240 includes a transfer robot 250. The transfer robot 250 conveys the substrate W in the conveying space. The transfer robot 250 may be located at the center of the conveying chamber 240. The transfer robot 250 may have a plurality of hands that may be moved in horizontal and vertical directions and may be moved forward, backward, or rotatably on a horizontal plane. Each hand can be independently driven, and the substrate W may be seated on the hand in a horizontal state.

The process chamber 260 generates plasma to perform an annealing process for selectively removing residues generated in the substrate W. The process chamber 260 may activate reaction gas to modify the reaction gas to a plasma state, so that cations or radicals of the reaction gas in the plasma state may selectively remove the residues generated in the substrate W.

In the process chamber 260, as a plasma generation source of generating plasma, a capacitive coupled plasma (CCP) source, an induced coupled plasma (ICP) source, an electron cyclotron resonance (ECR) plasma source using microwaves, a surface wave plasma (SWP) plasma source, or the like is provided.

According to the exemplary embodiment, the process chamber 260 may be provided as a process chamber capable of processing various processes which may be treated in the substrate treating process in addition to the annealing process. The process chamber 260 may be provided as a process chamber capable of performing an etching process.

The substrate treating apparatus according to the present invention may further include a control unit 300. The control unit 300 according to the present invention may control the transfer chamber to convey the substrate by applying the flow recipe. The control unit 300 may control a mode of the corresponding process chamber to be changed when there is a process chamber where abnormality occurs among the plurality of process chambers included in the flow recipe while the flow recipe is applied.

According to the present invention, a preceding job and a subsequent job start as a job to include all of the process chambers in the substrate treating apparatus, and when a state of a specific process chamber is changed, the state is reflected in real time and the introduction of the substrate is waiting and then when the mode is changed by the user, the substrate can be immediately introduced. As a result, when there is a problem in the specific process chamber in the related art, it is possible to solve a problem that a specific process chamber cannot be used even if the problem is solved. In addition, accordingly, there is an effect of improving the productivity of substrate treatment.

In the related art, when the job is executed, a flow recipe to operate each process chamber is made depending on the state of the process chamber and the flow recipe is selected according to the state of the process chamber to operate the job. In this case, in a Fab, when the state of the specific process chamber is changed according to the order of the job, a situation in which the corresponding process chamber is not immediately used occurs.

The control unit 300 according to the present invention may operate only one flow recipe as a case of operating all process chambers which may be operated by a substrate treating equipment and control the introduction of the substrate so as to minimize an idle time occurring in the process chamber by using a mode according to a situation of the process chamber. That is, the control unit 300 according to the present invention may set a flow recipe to include all of the process chambers capable of being operated by substrate treating equipment and control the mode to be changed only in the corresponding process chamber when abnormality occurs among all the process cambers, so that there is an effect of controlling the productivity to be increased much more than before.

According to the present invention, the flow recipe may be set in advance according to the number of used process chambers included in the substrate treating apparatus. In the present invention, the job may be executed by using a flow recipe capable of using all process chambers at all times at the start of the job corresponding to the execution of the flow recipe using this aspect.

In other words, in the present invention, both the preceding job and the subsequent job may be controlled to start as a job corresponding to all of the process chambers included in the equipment. Both the preceding job and the subsequent job may be processed as the same flow recipe.

According to the exemplary embodiment, the control unit 300 of the present invention may wait for the introduction of the substrate for a moment when the mode of the specific process chamber included in the flow recipe is changed and then immediately introduce the substrate when the mode is changed by the user.

The control unit 300 may further include a monitoring unit capable of monitoring whether the abnormality of the process chambers included in the flow recipe occurs. According to the exemplary embodiment, the monitoring unit may monitor whether the failure of the process chambers included in the flow recipe occurs and control the mode to be changed when the failure is detected.

According to the exemplary embodiment, in addition to the case where the abnormality of the process chamber occurs, even a case where there is no need that the corresponding substrate passes through the corresponding process chamber, it is possible to control the efficient substrate treatment to be performed by the change of the mode.

According to the exemplary embodiment, the mode which may be changed by the control unit 300 may be any one of a maintenance mode, an interlock mode, an offline mode, and an online mode.

According to the exemplary embodiment, the online mode may be a state in which the corresponding process chamber is normal. At this time, the substrate may be introduced to the corresponding process chamber.

According to the exemplary embodiment, the maintenance mode may be a mode of maintaining and repairing the corresponding process chamber. At this time, the substrate may not be introduced to the corresponding process chamber. According to the exemplary embodiment, the interlock mode may be a mode of blocking the substrate introduction to the corresponding process chamber for a test and the like. At this time, the treating substrate may not be introduced to the corresponding process chamber. According to the exemplary embodiment, in the interlock mode, the substrate for testing may be introduced. The offline mode may be a mode for turning off the corresponding process chamber to stop the operation of the corresponding process chamber itself. Even at this time, similarly, the substrate may not be introduced to the corresponding process chamber.

The control unit 300 may select and apply any of the four modes according to the state of the corresponding process chamber. According to the exemplary embodiment, when all of the process chambers are normal, all of the process chambers may be maintained in the online mode. According to the exemplary embodiment, the control unit 300 may determine whether to introduce the substrate according to each mode for the process chamber in which the abnormality occurs. The control unit 300 may control the substrate not to be introduced to the corresponding process chamber in the maintenance mode, the interlock mode, and the offline mode, and control the substrate to be introduced to the corresponding process chamber in the online mode.

Such a function can be changed in real time by interlocking with a host by changing the mode during the start of the job and the progression of the job. In addition, the function can be applied in real time to enable the efficient treatment.

The host may be provided in a user interface form. According to the exemplary embodiment, the mode of the process chamber may be changed using a SECS Message of the host. According to the exemplary embodiment, the host may provide the user with various options such as substrate introduction, recovery, maintenance, emergency job addition, and the like of the process chamber during the progression of the job.

According to the exemplary embodiment, when smart dynamic rescheduling (SDR) is configured in process job (PJ) information in association with the host to be transmitted to the substrate treating equipment, the usage or not of the specific process chamber when the execution of the of the initial job starts is set by using a specific attribute of the PJ and applied to the equipment to determine and operate the usage or not of the process chamber using the corresponding data. According to the exemplary embodiment, the mode of the process chamber may be set in the PJ information through an APC tuning or a remote command (RCMD) of the host.

According to the exemplary embodiment, since N parameter information may be used in a “PRRECIPEMETHOD” part of the internal parameter of the PJ, information of the process chamber which is not used in the PJ generation is set in the information in advance to introduce the substrate to another process chamber without introducing the substrate to the corresponding process chamber in the equipment.

According to the exemplary embodiment, when the usage information of the process chamber is changed after the PJ generation is completed, RCMD “S2F41” or “Stream Function Message (SxFx) of an undefined region” is defined to include or exclude a specific process chamber. The above message may be treated even when the PJ is in a queued state.

Hereinafter, a mode control method of the control unit 300 will be described through a specific example.

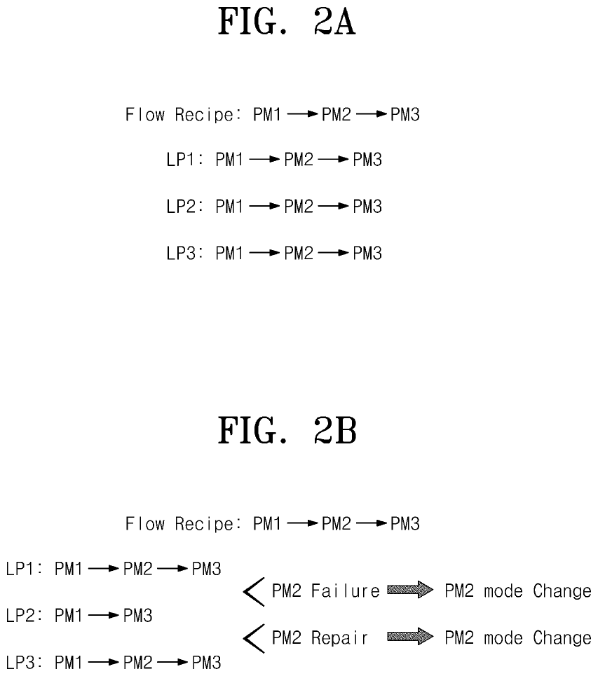

FIG. 2A is a diagram for describing performing substrate treatment using a flow recipe in a conventional method.

According to FIG. 2A, a predetermined flow recipe may be determined to pass through a process chamber 1 (PM 1), a process chamber 2 (PM 2), and a process chamber 3 (PM 3). Alternatively, a plurality of different flow recipes may be provided depending on the state, which may be selected according to the state of the process chamber.

In the convention method, when the substrate treatment is performed using a flow recipe, it is assumed that the substrate treatment is performed using the same flow recipe all in a first load port LP1, a second load port LP2, and a third load port LP3. In this case, sequentially, substrates included in the first load port LP1 are sequentially treated according to the flow recipe. According to the exemplary embodiment, the substrate may be treated in the order of a substrate included in the first load port LP1, a substrate included in the second load port LP2, and a substrate included in the third load port LP3.

However, when abnormality occurs in any one of the plurality of process chambers included in the flow recipe, there is a problem that it is difficult to directly control the corresponding process chamber in which the abnormality occurs. More specifically, in a mode for testing among various modes, there is a problem that a substrate to be treated needs to be immediately introduced, but there is a problem that it is not easy to adjust the mode and it is difficult to cope with the problem in the process chamber to be immediately generated.

FIG. 2B is a diagram for describing performing substrate treatment using a flow recipe in a method according to the present invention.

According to FIG. 2B, the flow recipe may be the provided same as in FIG. 2A. However, a difference is that when there is a chamber where abnormality occurs, the abnormality may be controlled to be reflected to the treating process in real time.

In FIG. 2B, it is assumed that all of the process chambers are normal during the treatment of the substrate included in the first load port LP1, the abnormality occurs in the process chamber 2 between the treatment of the substrate included in the first load port LP1 and the treatment of the substrate included in the second load port LP2, and the process chamber 2 is in a normal state between the treatment of the substrate included in the second load port LP2 and the treatment of the substrate included in the third load port LP3.

At this time, since there is no process chamber having the abnormality during the treatment of the substrate included in the first load port LP1, the substrate may be controlled to be treated according to the flow recipe. However, whether the abnormality has occurred in the process chamber 2 after the treatment of the substrate included in the first load port LP1 may be confirmed through monitoring. Since the abnormality has occurred in the process chamber 2, the control unit 300 may change the mode of the process chamber 2. According to the exemplary embodiment, the mode of the process chamber 2 may be changed to the offline mode. As a result, during the treatment of the substrate included in the second load port LP2, the process chamber 2 skips and the substrate may be treated only by the treating module 1 and the treating module 3. Since the abnormality has occurred in the process chamber 2, the control unit 300 may take a measure for normalizing the abnormality. As a result, the failure of the process chamber 2 is repaired, and the process chamber 2 may be normalized. When the process chamber 2 is normalized after the treatment of the substrate included in the second load port LP2, since the process chamber 2 may be sued during the treatment of the substrate included in the third load port LP3, the control unit 300 may change the mode of the process chamber 2 again. According to the exemplary embodiment, the control unit 300 may change the mode of the process chamber 2 online. Thus, the substrate may be treated by including process chamber 2 during the treatment of the substrate included in the third load port LP3.

That is, according to the present invention, while the flow recipe is set to include all of the process chambers included in the substrate treating equipment and the same flow recipe is applied to the plurality of substrates, the abnormality of the process chamber is determined, and as a result, when the abnormality occurs, the abnormality may be applied to the flow recipe in real time through the mode change. Accordingly, it is possible to significantly reduce the idle time as compared to the related art and very increase the substrate treating efficiency as compared to the related art.

In FIG. 2B, it has been described through an example in which the load ports are applied sequentially according to the flow recipe, but according to another exemplary embodiment of the present invention, when there are other empty process chambers other than the flow recipe sequence, the empty process chambers may also be controlled to be directly applied.

According to another exemplary embodiment of the present invention, the control unit may also set the flow recipe so as not to include all the plurality of process chambers included in the treating module. According to the exemplary embodiment, when the first process chamber, the second process chamber, and the third process chamber are present in the treating module, the flow recipe may be set in the order of the first process chamber -> the third process chamber.

At this time, it is assumed that the first load port and the second load port which are the plurality of load ports are treated according to the flow recipe. In this case, wafers included in the first load port may be treated in the order of the first process chamber and the third process chamber according to the flow recipe. Thereafter, wafers included in the second load port may also be treated in the order of the first process chamber and the third process chamber according to the flow recipe. However, when there is a need to use the second process chamber in the treatment of the flow recipe or the second process chamber is to be used such as a case where the second process chamber can be used in an unusable state, the control unit can include and treat the second process chamber immediately by changing the mode of the second process chamber.

That is, in the related art, there has been a problem that the process chamber that is not included in the flow recipe cannot use the corresponding process chamber before the flow recipe itself is changed. However, according to the present invention, a process chamber that is not included in the flow recipe for each load port can be immediately reflected through mode change, and the treatment is enabled by reflecting the state of the process chambers in real time for each load port, thereby increasing the efficiency.

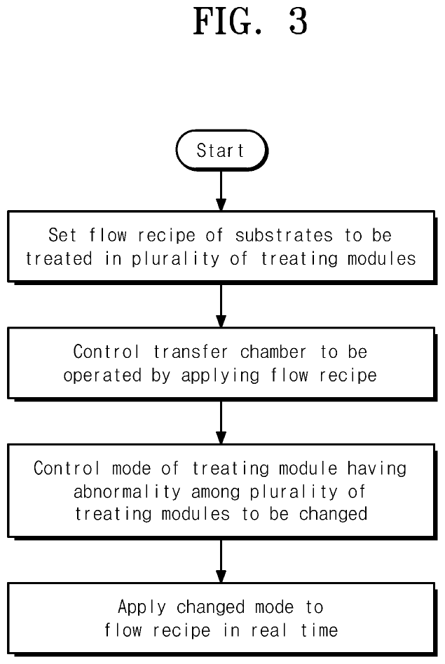

FIG. 3 is a flowchart illustrating a substrate treating method according to the present invention.

Referring to FIG. 3, there is disclosed a method for performing the substrate treatment using a plurality of process chambers. According to the exemplary embodiment, a flow recipe of substrates to be treated in the plurality of process chambers may be set. The flow recipe set at this time may include all the plurality of process chambers included in the substrate treating equipment. The control unit 300 may control the transfer camber conveying the substrate to be operated by applying the set flow recipe. At this time, the control unit 300 may monitor the state of the plurality of process chambers included in the flow recipe. The control unit 300 may control a mode of the corresponding process chamber to be changed when there is a process chamber where abnormality occurs among the plurality of process chambers included in the flow recipe while the job is executed. The changed mode may be applied to the flow recipe in real time. According to the exemplary embodiment, when the corresponding process chamber has a fault, the corresponding process chamber is included in the flow recipe, but the control unit 300 may skip the corresponding process chamber and control another treatment to be performed. According to the exemplary embodiment, when the maintenance of the corresponding process chamber is completed, the control unit 300 may control the job to be executed by including the corresponding process chamber again.

It is to be understood that the exemplary embodiments are presented to assist in understanding of the present invention, and the scope of the present invention is not limited, and various modified exemplary embodiments thereof are included in the scope of the present invention. The drawings provided in the present invention are only illustrative of an optimal exemplary embodiment of the present invention. The technical protection scope of the present invention should be determined by the technical idea of the appended claims, and it should be understood that the technical protective scope of the present invention is not limited to the literary disclosure itself in the appended claims, but the technical value is substantially affected on the equivalent scope of the invention.

1. A substrate treating apparatus for performing treatment of a plurality of substrates, comprising:
a load port configured to load a conveying container for receiving the plurality of substrates;
a plurality of process chambers configured to perform the treatment of the plurality of substrates;
a transfer chamber configured to convey each of the plurality of substrates between the load port and a corresponding one of the plurality of process chambers; and
a control unit configured to control the transfer chamber to convey the plurality of substrates by applying a flow recipe,
wherein the control unit controls a mode of the corresponding process chamber to be changed when abnormality occurs to the corresponding process chamber while the flow recipe is applied.

2. The substrate treating apparatus of claim 1,
wherein the mode is one of a maintenance mode, an interlock mode, an offline mode, and an online mode.

3. The substrate treating apparatus of claim 2,
wherein the control unit determines whether or not to introduce the substrate according to a mode for each of the plurality of process chambers.

4. The substrate treating apparatus of claim 3,
wherein the control unit controls is configured such that a substrate is not to be introduced to each process chamber, in one of the maintenance mode, the interlock mode, and the offline mode, among the plurality of process chambers, and the substrate is to be introduced to each process chamber, in the online mode, among the plurality of process chambers.

5. The substrate treating apparatus of claim 1,
wherein the control unit controls the change of the mode even when a job is performing according to the flow recipe.

6. The substrate treating apparatus of claim 5,
wherein the control unit controls the plurality of substrates using the flow recipe.

7. The substrate treating apparatus of claim 6,
wherein the same flow recipe is set to include all of the plurality of process chambers.

8. The substrate treating apparatus of claim 5,
wherein the control unit is interlocked with a host.

9. The substrate treating apparatus of claim 8,
wherein the change of the mode is performed using a SECS Message of the host.

10.-17. (canceled)

18. A substrate treating apparatus for performing treatment of a plurality of substrates, comprising:
a plurality of load ports configured to load a conveying container for receiving the plurality of substrates;
a plurality of process chambers configured to perform the treatment of the plurality of substrates;
a transfer chamber configured to convey the plurality of substrates between the plurality of load ports and the plurality of process chambers; and
a control unit configured to control the transfer chamber to convey the plurality of substrates by applying a flow recipe,
wherein the plurality of load ports include a first load port and a second load port,
wherein the plurality of process chambers include a first process chamber, a second process chamber, and a third process chamber,
wherein the flow recipe of the first load port and the second load port is the order of the first process chamber and the third process chamber, and
wherein the control unit controls the flow recipe to be performed by including the second process chamber when the second process chamber is operable during the flow recipe treatment of the second load port.

19. The substrate treating apparatus of claim 18,
wherein the control unit changes a mode of the second process chamber to any one of a maintenance mode, an interlock mode, an offline mode, and an online mode.

20. The substrate treating apparatus of claim 19,
wherein the control unit controls the substrate not to be introduced to the second process chamber in the maintenance mode, the interlock mode, and the offline mode, and controls the substrate to be introduced to the second process chamber in the online mode.
